(19) United States
(12) Patent Application Publication
(10) Pub. No.: US 2021/0255727 A1
(43) Pub. Date: Aug. 19, 2021

(54) SENSOR DIAGNOSTICS FOR IN-CELL TOUCH SCREEN CONTROLLERS

(71) Applicant: Cypress Semiconductor Corporation, San Jose, CA (US)

(72) Inventors: Oleksandr Pirogov, Lviv (UA); Viktor Kremin, Lviv (UA); Vadym Grygorenko, Lviv (UA); Jens Weber, Munich (DE)

(73) Assignee: Cypress Semiconductor Corporation, San Jose, CA (US)

(21) Appl. No.: 17/026,892

(22) Filed: Sep. 21, 2020

Related U.S. Application Data
(60) Provisional application No. 62/977,923, filed on Feb. 18, 2020.

(51) Int. Cl. G06F 3/041; G06F 3/044; G01R 31/52; G01R 31/54

(52) U.S. Cl. CPC G06F 3/0418; G06F 3/044; G06F 2203/04107; G01R 31/52; G01R 31/54; G06F 3/04166

(57) ABSTRACT

Described herein are devices, methods, and systems that detect the presence of faults such as shorts and/or opens within a touch sensitive display panel. In one embodiment, a touch screen controller is disclosed, the touch screen controller comprising one or more receive channels, where each receive channel is configured to scan a corresponding group of sensors of a plurality of sensors. The touch screen controller may also comprise a plurality of multiplexers, each multiplexer configured to selectively couple a respective sensor of the plurality of sensors to a corresponding receive channel or a reference voltage. The touch screen controller may further comprise a processing device configured to detect one or more shorts based on DC current sensing. The touch screen controller may also detect one or more opens based on AC current sensing of each of the one or more receive channels.

### CROSS REFERENCE TO RELATED APPLICATIONS

This application claims the benefit of U.S. Provisional Application No. 62/977,923, filed Feb. 18, 2020, the disclosure of which is incorporated herein in its entirety.

### TECHNICAL FIELD

The present disclosure relates generally to touch and/or presence-based display systems, and more particularly to display controllers with display sensor diagnostic capabilities.

### BACKGROUND

Capacitance sensing systems can sense electrical signals generated on electrodes that reflect changes in capacitance. Such changes in capacitance can indicate a touch event such as physical contact of or the proximity of an object to particular electrodes. Capacitive sensor arrays work by measuring the capacitance of a capacitive sensor (e.g., an electrode) and evaluating for a delta in capacitance indicating a touch or presence of a conductive object. When a conductive object (e.g., a finger, hand, or other object) comes into contact or close proximity with a capacitive sensor, the capacitance changes and the conductive object is detected. The capacitance changes can be measured by an electrical circuit. The electrical circuit converts the signals corresponding to measured capacitances of the capacitive sensors in the array into digital values. The measured capacitances are generally received as currents or voltages that are integrated and converted to the digital values.

Capacitive sensors are widely used in modern customer applications, providing user interface options in existing products. Capacitive sensors may be used to replace mechanical buttons, dials/knobs, and other similar mechanical user interface controls. The use of capacitive sensors may replace the functionality of complicated mechanical switches and buttons, providing reliable operation under harsh conditions. In addition, capacitive sensors can range from a single button to a large number arranged in the form of a capacitive sense array for a touch-sensing surface. Capacitive sensor arrays are ubiquitous in today's industrial and consumer markets. They can be found in automobiles, cellular phones, GPS devices, set-top boxes, cameras, computer screens, MP3 players, digital tablets, and the like.

There are two typical types of capacitance generally used in capacitive sensing: 1) mutual capacitance where the capacitance-sensing circuit measures a capacitance formed between two sensors coupled to the capacitance-sensing circuit; and 2) self-capacitance where the capacitance-sensing circuit measures a capacitance of one sensor. A touch panel has a distributed load of capacitance of both types (1) and (2) and some touch solutions sense both capacitances either uniquely or in hybrid form with its various sense modes.

### BRIEF DESCRIPTION OF THE DRAWINGS

The present embodiments are illustrated by way of example, and not of limitation, in the figures of the accompanying drawings.

FIG. 1 is a block diagram illustrating a capacitive touchscreen display, according to some embodiments of the present disclosure.

FIG. 2 is a block diagram illustrating a touch screen controller, according to some embodiments of the present disclosure.

FIGS. 3A-3B are diagrams illustrating a sensor array during various stages of short detection, according to some embodiments of the present disclosure.

FIG. 4 is a diagram illustrating a touch screen controller, according to some embodiments of the present disclosure.

FIG. 5 is a diagram illustrating a sensor array during short detection, according to some embodiments of the present disclosure.

FIG. 6 is a diagram illustrating half period data of a receive channel during short detection, according to some embodiments of the present disclosure.

FIG. 7 is a block diagram illustrating a touchscreen display, in accordance with some embodiments of the present disclosure.

FIG. 8 is a flow diagram of a method for detecting shorts in a touchscreen display, in accordance with some embodiments of the present disclosure.

FIG. 9 is a flow diagram of a method for detecting shorts in a touchscreen display, in accordance with some embodiments of the present disclosure.

FIG. 10 is a flow diagram of a method for detecting opens in a touchscreen display, in accordance with some embodiments of the present disclosure.

FIG. 11 illustrates an embodiment of a core architecture of a Programmable System-on-Chip (PSoC®) micro-controller.

### DETAILED DESCRIPTION

In the following description, for purposes of explanation, numerous specific details are set forth in order to provide a thorough understanding of the present embodiments. It will be evident, however, to one skilled in the art that the present embodiments may be practiced without these specific details. In other instances, well-known circuits, structures, and techniques are not shown in detail, but rather in a block diagram in order to avoid unnecessarily obscuring an understanding of this description.

Reference in the description to “one embodiment” or “an embodiment” means that a particular feature, structure, or characteristic described in connection with the embodiment is included in at least one embodiment. The phrase “in one embodiment” located in various places in this description does not necessarily refer to the same embodiment.

Capacitive sensor arrays are ubiquitous in today's industrial and consumer markets. Capacitive sense elements may be used to replace the functionality of mechanical buttons, dials/knobs, and other similar mechanical user interface controls. However, capacitive sense arrays are subject to faults and defects. For example, capacitive sense arrays may be subject to shorts, where multiple sensors are shorted, either on the panel itself or at the bonding of the integrated circuit where the sensors are realized. Another example of a fault is an “open,” which is a broken connection between traces of a sensor. Because these faults can affect the performance of the touch sensing display, detection of such faults, particularly in contexts such as automotive displays, is important. Sensor diagnostics procedures must be able to execute at run-time of the display module and, while running, must not disturb the displayed image.

The structure of a touch sensing display panel may include a number of layers such as a cover glass, a color filter glass, insulation, a color filter, one or more polarizers, a liquid crystal (LCD) layer, a common layer (VCOM), a layer where a display driver may be implemented, and a layer where a touch screen controller may be implemented. There are numerous ways that a display panel may be realized. For example, in an on-cell configuration, both of the top (TX & RX) sense layers are above the color filter glass substrate, but below the top polarizer. The LCD layers do not include the display driver or touch screen controller (capacitive sensing) functionality, and thus dedicated layers are required for the display driver or touch screen controller. In a hybrid in-cell configuration, the structure includes one capacitive sensing layer above the color filter glass and one below. The LCD layers can include the touch screen controller functionality but a separate layer is still required for the display driver functionality. In a true in-cell configuration, the structure integrates the touch screen controller and display driver functionality within the VCOM layer, and no additional layers are required.

The embodiments described herein are directed at detecting the presence of faults such as shorts and/or opens within a touch sensitive display panel. The display panel may include a touch screen comprising a capacitive sensor array and a touch screen controller operatively coupled to the touch screen. The sensor array may comprise a plurality of capacitive sensors and the touch screen controller may be operatively coupled to the capacitive sensor array in any appropriate configuration (e.g., true in-cell, on-cell, hybrid in-cell etc.).

Described herein are devices, methods, and systems that detect the presence of faults such as shorts and/or opens within a touch sensitive display panel. In one embodiment, a touch screen controller is disclosed, the touch screen controller comprising: one or more receive channels, where each receive channel is configured to scan a corresponding group of sensors of a plurality of sensors. The touch screen controller further comprises a plurality of multiplexers, and each multiplexer is configured to selectively couple a respective sensor of the plurality of sensors to a corresponding receive channel or a reference voltage. The touch screen controller further comprises a processing device configured to: detect one or more shorts using DC current sensing as well as detect one or more opens based on AC current sensing of each of the one or more receive channels.

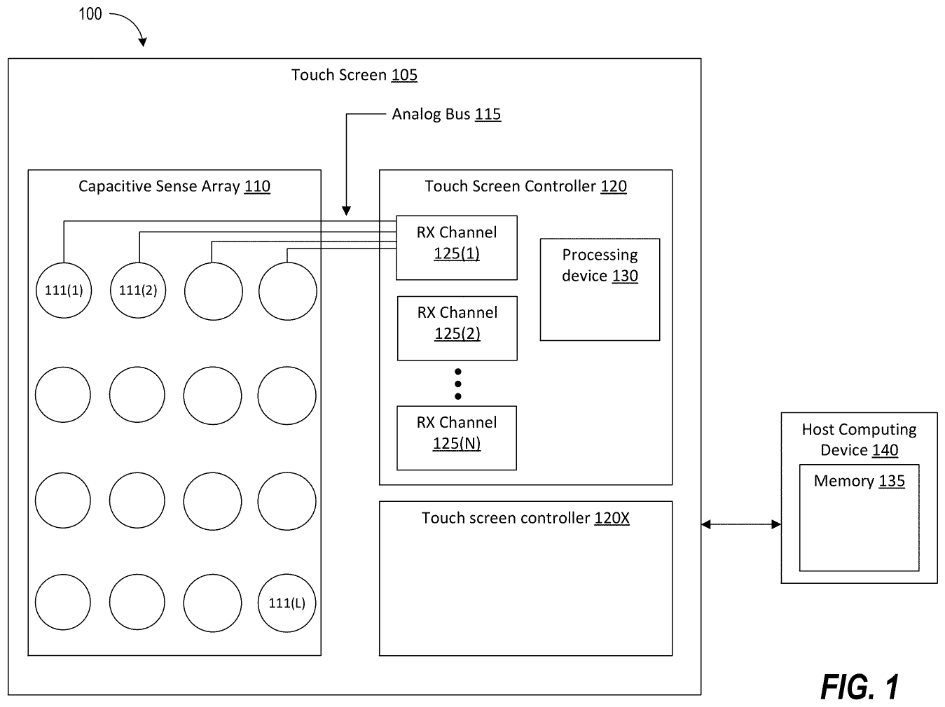

FIG. 1 is a block diagram illustrating one embodiment of a touch screen display 100. The touch screen display 100 may comprise a touch screen 105 and a touch screen controller 120. The touch screen 105 may be a display screen for displaying images and may include a number of layers including a cover glass, a color filter glass, a color filter, a polarizer, a liquid crystal, and a common layer (VCOM), in which a capacitive sense array 110 may be implemented. In some embodiments, the touch screen controller 120 may be integrated into the VCOM layer of the touch screen 105, and may be configured to measure capacitances from the capacitive sense array 110. This configuration may be referred to as an “in-cell” configuration, as the touch screen controller functionality is implemented entirely on the VCOM layer without the need for additional layers. The touch screen controller 120 may integrate touch screen controller and display driver functionality together on one chip. Touch screen controller functionality may refer to sensing of a touch by, or proximity of, a conductive object, and display driver functionality may refer to the refreshing of images displayed on the touch screen 105. In some embodiments, the touch screen 105 (e.g., a touchscreen, or a touch pad) may be coupled to a host computing device 140. In some embodiments, the capacitive sense array 110 is a two-dimensional sense array that uses touch screen controller 120 to detect touches on the touch screen 105.

In some embodiments, the capacitive sense array 110 includes electrodes 111(1)-111(L) (where L is a positive integer) that are disposed as a two-dimensional matrix (also referred to as an XY matrix). The capacitive sense array 110 is coupled to the touch screen controller 120 via one or more analog buses 115 that transport multiple signals. The capacitive sense array 110 may be a multi-dimension capacitive sense array, organized as rows and columns. In yet other embodiments, the capacitive sense array 110 is non-transparent capacitive sense array (e.g., PC touchpad). The capacitive sense array 110 may be disposed to have a flat surface profile. Alternatively, the capacitive sense array 110 may have non-flat surface profiles. Alternatively, other configurations of capacitive sense arrays may be used. For example, instead of vertical columns and horizontal rows, the capacitive sense array 110 may have a hexagon arrangement, or the like, as would be appreciated by one of ordinary skill in the art having the benefit of this disclosure. In one embodiment, the capacitive sense array 110 may be included in an ITO panel or a touch screen panel.

In some embodiments, the touch screen controller 120 may include one or more receive (RX) channels 125(1)-125(N) to measure charge on the electrodes 111 (also referred to herein as “sensors”). There are various methods of measuring capacitance on the capacitive sense array 110, such as self-capacitance sensing and mutual capacitance sensing. RX channels 125 may use any appropriate technique for measuring capacitance. For example, the RX channels 125 may each include a relaxation oscillator or other means to measure capacitance and a counter or timer to measure the oscillator output. Alternatively, the RX channels 125 may each include an operational amplifier, a switch, and an integrator capacitor. Other capacitance sensing methods known by those skilled in the art may also be utilized. In an embodiment, the touch screen controller 120 is of the Cypress PSoC® family of micro-controllers developed by Cypress Semiconductor™ Corporation, of San Jose, Calif. The RX channels 125 measure the signals representing the self-capacitance of the electrodes 111(1)-111(L). The touch screen controller 120 also includes a converter circuit (not shown), such an analog-to-digital converter (ADC) that converts the measured signals into digital values. The touch screen controller 120 may further include software components to convert the count value (e.g., capacitance value) into a touch detection decision (also referred to as switch detection decision) or relative magnitude. It should be noted that there are various known methods for measuring capacitance, such as current versus voltage phase shift measurement, resistor-capacitor charge timing, capacitive bridge divider, charge transfer, successive approximation, sigma-delta modulators, charge-accumulation circuits, field effect, mutual capacitance, frequency shift, or other capacitance measurement algorithms. It should be noted however, that in some embodiments, instead of evaluating the raw counts relative to a threshold, the touch screen controller 120 may be evaluating other measurements to determine the user interaction. For example, in the touch screen controller 120 having a sigma-delta modulator, the touch screen controller 120 is evaluating the ratio of pulse widths of the output (i.e., density domain), instead of the raw counts being over or under a certain threshold. It should be noted that the RX channels 125 may be one type of sensing channel that can be configured for different operational modes. For example, the RX channels 125 in a self-capacitance mode are configured as sensing channels for driving and sensing an electrode 111 to measure a self-capacitance of the electrode relative to ground or any appropriate reference voltage. Although embodiments of the present disclosure are discussed with respect to self-capacitance sensing, the RX channels 125 can also be configured to be sensing channels for a mutual capacitance mode in which a mutual capacitance between a first electrode (RX) and a second electrode (TX) is measured. Alternatively, the RX channels can be configured for a self-capacitance and mutual capacitance mode in which self-capacitance and mutual capacitance can be measured concurrently or sequentially.

The touch screen controller 120 is configured to detect one or more touches on the touch screen 105. The touch screen controller 120 can detect conductive objects, such as fingers, a passive stylus, an active stylus, or any combination thereof. As used herein, detecting a conductive object may refer to detecting the proximity of a conductive object to the touch screen 105 or actual physical contact between the conductive object and the touch screen 105. The touch screen controller 120 can measure touch data on the capacitive sense array 110.

The sensors 111 may be electrodes of conductive material, such as copper, while the touch screen 105 is an ITO panel. The sensors 111 can be configurable to allow the touch screen controller 120 to measure self-capacitance, mutual capacitance, or any combination thereof. In another embodiment, the touch data is a 2D capacitive image of the capacitive sense array 110. In one embodiment, when the touch screen controller 120 measures mutual capacitance of the touch-sensing device (e.g., capacitive sense array 110), the touch screen controller 120 obtains a 2D capacitive image of the touch-sensing device and processes the data for peaks and positional information. In another embodiment, the touch screen controller 120 obtains a capacitance touch signal data set, such as from the sense array 110, and finger detection firmware executing on the touch screen controller 120 identifies data set areas that indicate touches, detects and processes peaks, calculates the coordinates, or any combination therefore. The firmware identifies the peaks using the embodiments described herein. The firmware can calculate a precise coordinate for the resulting peaks. In one embodiment, the firmware can calculate the precise coordinates for the resulting peaks using a correlation algorithm, which calculates a correlation coefficient of each possible angle, and identifies the angle having the highest correlation coefficient as the position of the touch. The X/Y coordinates of the peak may describe the exact position of the touch, as described in further detail herein. Alternatively, other coordinate interpolation algorithms may be used to determine the coordinates of the resulting peaks. The touch screen controller 120 can report the precise coordinates to a host computing device (not shown), as well as other information.

In one embodiment, operations of the touch screen controller 120 may be implemented in on-board firmware. In other embodiments, they may be implemented in hardware or software. For example, the operations of the touch screen controller 120 may be stored as instructions in memory 135, located separately from touch screen controller 120 (e.g., because the high voltage display driver process is not compatible with known flash technology) which the touch screen controller 120 may execute to perform its functions. For example, touch screen controller 120 may include one or more processing devices 130 (a single processing device is illustrated in FIG. 1 for ease of illustration) to execute instructions in memory 135 to perform the functions. The processing device 130 may receive signals from the RX channels 125, and determine the state of the capacitive sense array 110, such as whether an object (e.g., a finger) is detected on or in proximity to the sense array 110 (e.g., determining the presence of the object), resolve where the object is on the sense array (e.g., determining the location of the object), tracking the motion of the object, or other information related to an object detected at the touch sensor. The processing device 130 may be any appropriate central processing unit (CPU).

In another embodiment, instead of performing the operations of the processing device 130 in the touch screen controller 120, the touch screen controller 120 may send the raw data or partially-processed data to the host computing device 140. The host computing device 140 (hereinafter referred to as “the host 140”) may include logic that performs some or all of the operations of the processing device 130. Operations of the decision logic may be implemented in firmware, hardware, software, or a combination thereof. The host 140 may include a high-level Application Programming Interface (API) in applications that perform routines on the received data, such as compensating for sensitivity differences, other compensation algorithms, baseline update routines, start-up and/or initialization routines, interpolation operations, or scaling operations. The operations described with respect to the processing device 130 may be implemented in the logic, applications, or in other hardware, software, and/or firmware of the host 140. The host 140 may also include non-sensing actions hardware or software which may be used to process and/or receive/transmit data to and from the host. For example, additional components may be implemented to operate with the touch screen controller 120 along with the capacitive sense array 110 (e.g., keyboard, keypad, mouse, trackball, LEDs, displays, or other peripheral devices).

In an embodiment, the sensors 111 are configured in rows and columns, respectively. It should be noted that the rows and columns of sensors 111 can be configured by the touch screen controller 120 as individual electrodes for self-capacitance measurements. The touch screen controller 120 via e.g., a multiplexer, can configure the electrodes 111 as RX electrodes for self-capacitance sensing, and one or more electrodes as barrier electrodes. In some embodiments, the touch screen controller 120 can also configure some electrodes 111 to be driven by a shield signal.

In some embodiments, the touch screen 105 may include multiple touch screen controllers 120, which may all reside with the capacitive sense array 110 on a common carrier substrate such as, for example, an integrated circuit (IC) die substrate, or a multi-chip module substrate. In these embodiments, a first touch screen controller 120 may act as a master controller, and may function to scan certain sensors of the capacitive sense array 110, and the other touch screen controllers 120X may act as slave controllers to scan the remaining sensors of the capacitive sense array 110.

Descriptions of touch screen controller 120 may be generated and compiled for incorporation into an integrated circuit. For example, behavioral level code describing the touch screen controller 120, or portions thereof, may be generated using a hardware descriptive language, such as VHDL or Verilog, and stored to a machine-accessible medium (e.g., CD-ROM, hard disk, floppy disk, etc.). Furthermore, the behavioral level code can be compiled into register transfer level (“RTL”) code, a netlist, or even a circuit layout and stored to a machine-accessible medium. The behavioral level code, the RTL code, the netlist, and the circuit layout may represent various levels of abstraction to describe touch screen controller 120.

In one embodiment, the touch screen display 100 is used in a tablet computer. Alternatively, the electronic device may be used in other applications, such as a notebook computer, a mobile handset, a personal data assistant (“PDA”), a keyboard, a television, a remote control, a monitor, a handheld multi-media device, a handheld media (audio and/or video) player, a handheld gaming device, a signature input device for point of sale transactions, an eBook reader, global position system (“GPS”) or a control panel. The embodiments described herein are not limited to touch screens or touch-sensor pads for notebook implementations, but can be used in other capacitive sensing implementations, for example, the sensing device may be a touch-sensor slider (not shown) or touch-sensor buttons (e.g., capacitance sensing buttons). In one embodiment, these sensing devices include one or more capacitive sensors or other types of capacitance-sensing circuitry. The operations described herein are not limited to notebook pointer operations, but can include other operations, such as lighting control (dimmer), volume control, graphic equalizer control, speed control, or other control operations requiring gradual or discrete adjustments. It should also be noted that these embodiments of capacitive sensing implementations may be used in conjunction with non-capacitive sensing elements, including but not limited to pick buttons, sliders (ex. display brightness and contrast), scroll-wheels, multi-media control (ex. volume, track advance, etc.) handwriting recognition, and numeric keypad operation.

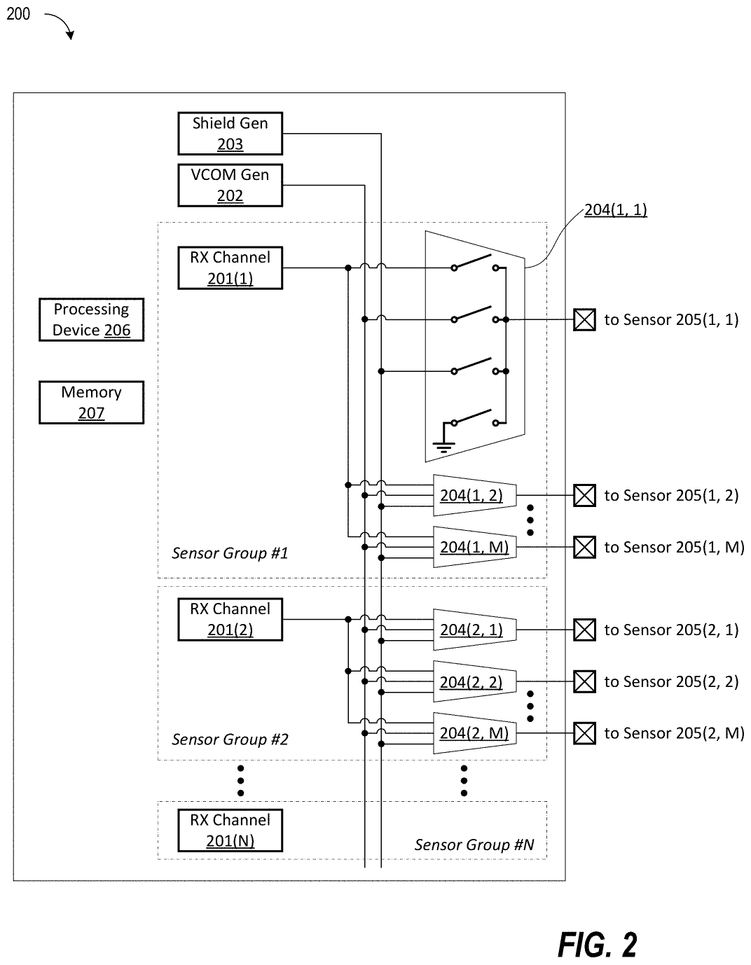

As discussed in further detail with respect to FIGS. 2-9, the touch screen controller 120 may provide the ability to detect faults of various types at run-time of the touch screen display 100. One example of a fault may be a “short,” where more than 2 sensors are shorted, either on the panel itself or at the bonding of the integrated circuit where the sensors are realized. Another example of a fault is an “open,” which is a broken connection between traces of a sensor. Opens may be found in a variety of locations including both on the pad of the IC or on the display panel itself. The fault detection provided may be operative during operation of the display and may avoid not distortion or disruption of the display of the image during operation. As used herein, a “scan” of an electrode or sensor may refer to an RX channel driving the sensor (in a self-capacitance mode) to measure a capacitance of the sensor relative to ground or any appropriate reference voltage. In addition, a “touch scan” of a sensor array may refer to obtaining capacitance measurements from (e.g., “scanning”) each sensor in the array to detect the presence or proximity of a conductive object. Thus, a touch scan of a sensor array may include multiple scans of the various electrodes or sensors that the sensory array is comprised of FIG. 2 illustrates a touch and display driver integration (TTDI) controller 200 (hereinafter referred to as “touch screen controller 200”) using a special multiplexing structure as shown. The touch screen controller 200 may be a more detailed representation of the touch screen controller 120 illustrated in FIG. 1. Each RX channel 201 may address (e.g., be connected to) M different sensors (M sensors forming a sensor group), so that each RX channel 201 may address a corresponding sensor group. There may be N RX channels 201 thereby forming N sensor groups, so that the ratio of RX channels to the number of all sensors is N:L=1:M (e.g. 1:6). The common layer (VCOM) generator 202 drives the sensors 205 during a display refresh interval by generating a DC level from time frame to time frame. The shield generator 203 may be a programmable arbitrary waveform generator. During a capacitive sensing time window, the shield generator 203 may apply a copy of the waveform (referred to as a compensation signal) of the sensors 205 driven by RX channels 201 to gate lines and data lines of the display and to unused sensors 205. More specifically, the shield generator 203 may match the phase and amplitude of the waveform produced by RX channels 201, so that the capacitance seen by each RX channel 201 is minimized. Otherwise, a parasitic coupling forms between each RX channel 201, unused sensors 205, gate lines and data lines of the display. Touch screen controller 200 may also include a memory 207 comprising instructions for performing the scanning methods described below and a processing device 206 to execute the instructions. In some embodiments, the instructions for performing the scanning methods described below may be implemented as firmware within processing device 206. In other embodiments, the memory 207 may be located on a separate device and may be communicatively coupled to the processing device 206. Touch screen controller 200 may also include components such as analog to digital converters (ADCs) which have been omitted from FIG. 2 for ease of illustration.

Each multiplexer 204 may couple a respective sensor 205 to an RX channel 201 corresponding to the sensor group the respective sensor 205 is a part of. More specifically, each multiplexer 204 may selectively couple a sensor 205 to a corresponding RX channel 201, the VCOM generator 202, and the shield generator 203 simultaneously, or to a ground (GND). In some embodiments, each multiplexer 204 may selectively couple a sensor 205 to a corresponding RX channel 201, the VCOM generator 202, and the shield generator 203 simultaneously, or to a programmable DC source (e.g., the shield generator 203). In this way, each RX channel 201 may couple to and scan each sensor 205 in the RX channel 201's sensor group sequentially. Hereinafter, the RX channels 201 are addressed by index i=[1; N]. Hereinafter, the multiplexers 204 and the sensors 205 are addressed by two indices (i, j), where the first index, i, defines the RX channel index the corresponding multiplexer and sensor can be connected to (i=[1; N]), and where the second index, j, defines the sensor index within i-th sensor group the corresponding multiplexer and sensor belong to (j=[1; M]). When RX channel 201(1) is coupled to sensor 205(1,1) via multiplexer 204(1,1), multiplexers 204(1,2)-204(1,M) may couple sensors 205(1,2)-205(1,M) to GND (or a programmable DC source). Similarly, when RX channel 201(1) is coupled to sensor 205(1,2) via multiplexer 204(1,2), other multiplexers 204(1,1)-204(1,M), excluding 204(1,2), may couple other sensors 205(1,1)-205(1,M), excluding 205(1,2), to GND or a programmable DC source. Both the GND and a programmable DC source may be referred to as examples of a reference voltage.

In some embodiments, the touch screen controller 200 may perform short detection using DC current sensing between a sensor connected to an RX channel and grounded sensors. A short creates a current path from an enabled RX channel to GND, which affects the ADC conversion result. Legacy on-cell shorts testing technology requires a scan per sensor (with the rest sensors grounded). Thus, if an in-cell panel consists of 960 sensors, then a shorts test will take 960 scans using the legacy technique.

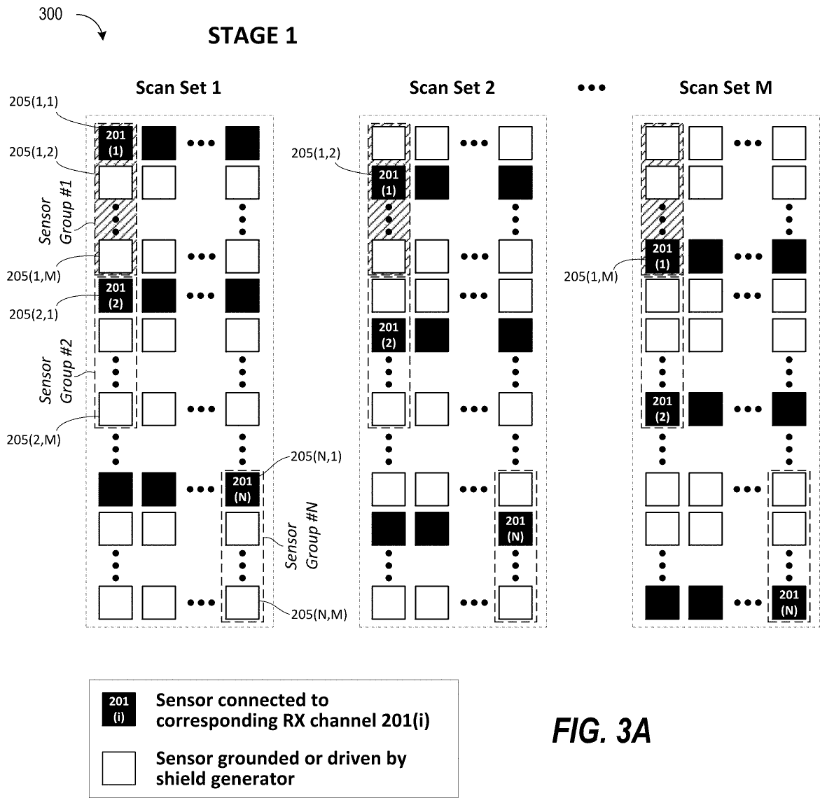

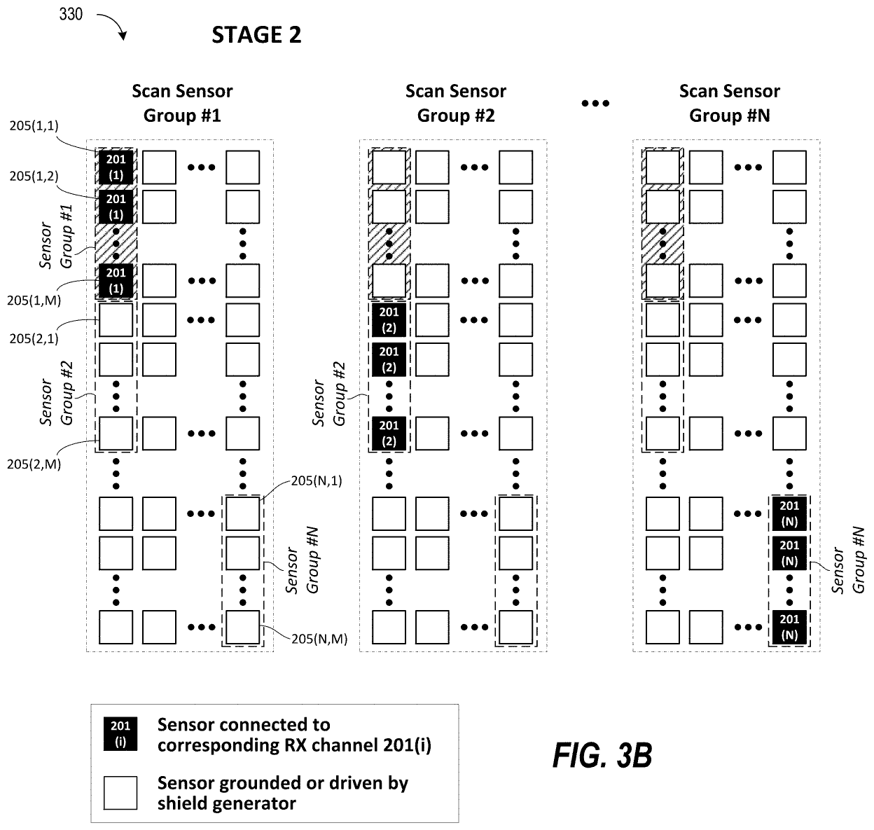

FIG. 3A illustrates a first stage of the DC current sensing method wherein the touch screen controller 200 may detect shorts within sensor groups in accordance with embodiments of the present disclosure. The touch screen controller 200 may perform M scan sets, each of the M scan sets using (scanning) all of the RX channels 201 in parallel. During each of the M scan sets, only one sensor 205 in each sensor group is connected (indicated in FIG. 3A by shaded sensors 205) to the corresponding RX channel 201 at the moment of scan. For example, in sensor group 1, sensor 205(1,1) may be connected to RX channel 201(1) by the corresponding multiplexer 204(1,1). Unused sensors 205(1,2)-205(1,M) (indicated in FIG. 3A by unshaded sensors 205) are connected to GND via their respective multiplexer 204. Touch screen controller 200 may perform a DC scan, so no AC excitation may be applied to the connected sensor 205(1,1). There is some potential of the connected sensor 205(1,1) that differs from GND (or a programmable DC level) of the unused sensors 205(1,2)-205(1,M), and this difference in voltage forms a current pass which forms a leakage current which may be detected. Touch screen controller 200 may perform the remaining M scan sets in a similar manner, sequentially connecting each RX channel 201 to a different sensor 205 of its group each time. The touch screen controller 200 may perform each of the M scan sets in this way, and then check the ADC readings to determine if they are within a manufacturing variation range. The touch screen controller 200 may report a test failure if the measured data exceeds the manufacturing variation range limits.

FIG. 3B illustrates the second stage of the DC current sensing method wherein the touch screen controller 200 may detect shorts between sensor groups. The touch screen controller 200 may perform N scans sequentially, where for each scan, a single channel 201 is connected to all sensors 205 in the corresponding sensor group. For example, in a first scan, RX channel 201(1) may be connected to sensors 205(1,1)-205(1,M), and unused sensors (e.g., sensors 205 on any other RX channel 201(2)-201(N)) are connected to GND (or a programmable DC source). The touch screen controller 200 may perform each of the N scans in this way, and then check the ADC readings to determine if they are within a manufacturing variation range. The FW reports a test failure if measurement data exceeds the manufacturing variation range limits.

As can be seen, for an in-cell panel with 960 sensors, and touch screen controller 200 having 160 RX channels (N=160) and 1:6 MUX ratio (M=6), the number of scans required may be given as M+N=6+160=166. Therefore, the test time may be reduced ˜M times compared to the legacy test technique which requires M×N=6×160=960 scans.

In some embodiments, if the grounding of unused sensors impacts the picture on display, instead of grounding unused sensors, touch screen controller 200 may drive them (and any other nodes that define parasitic capacitance seen by the RX channels 201) with a programmable constant voltage produced by the shield generator 203. Touch screen controller 200 may modulate the compensation signal of the shield generator 203 so that the difference in ADC readings between normal sensors and a broken sensor is detectable and can be determined algorithmically. In some embodiments, the touch screen controller 200 may use some intermediate voltage close to the touch scan reference voltage for the compensation signal.

As can be seen, the use of DC current sensing for short testing and diagnosis does not require additional hardware, but cannot be performed as part of a standard touch scan and requires a separate diagnostics scan.

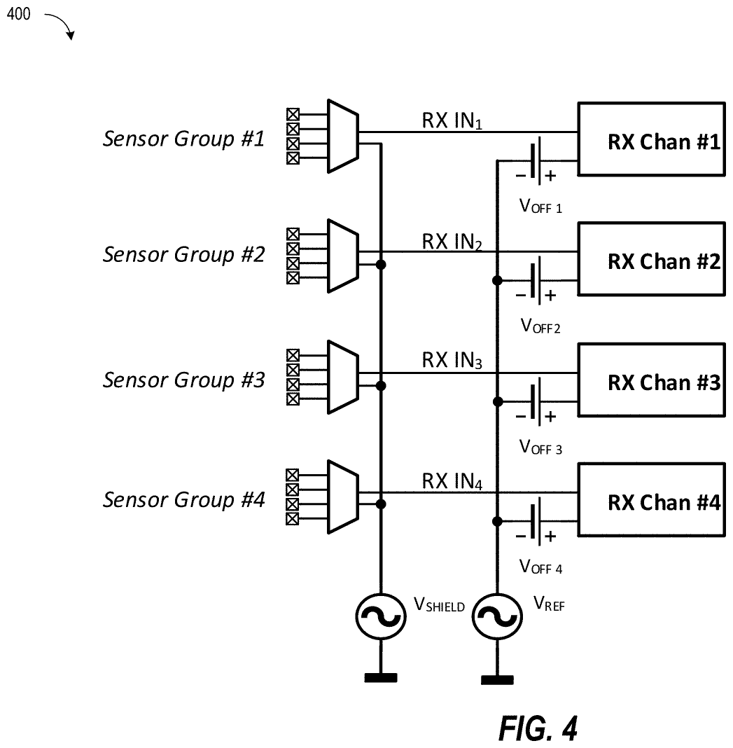

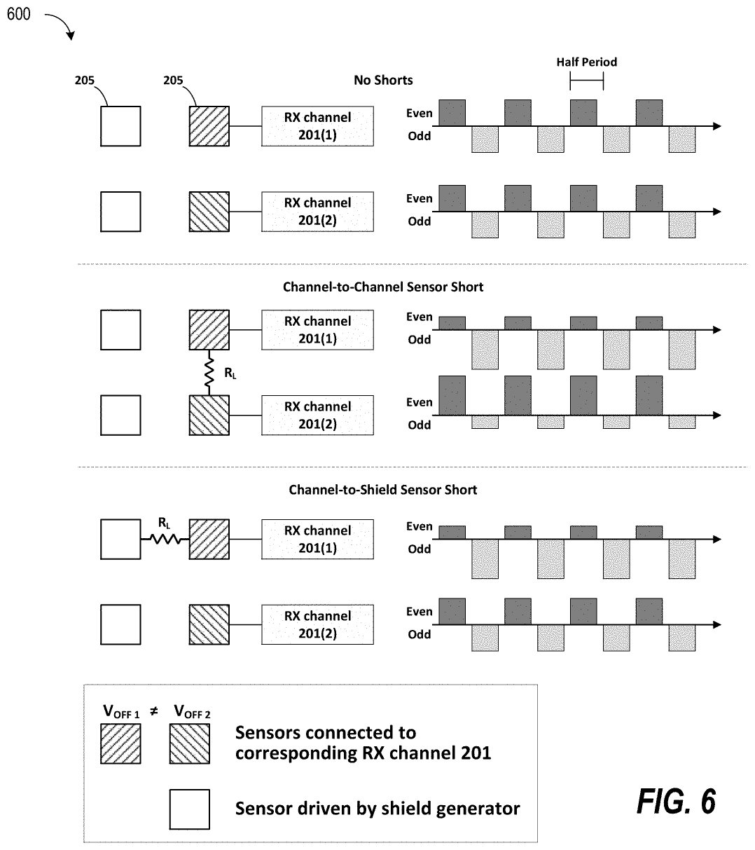

The second method of testing for shorts utilizes individual DC offset voltages (programmable or constant) for each sensing channel. The use of individual DC offset voltages allows for short diagnostics to be performed in parallel during a scan. FIG. 4 illustrates the touch screen controller 200 of FIG. 2, and more specifically illustrates the RX channels 201 of FIG. 2, with offset voltage sources for shorts testing. As can be seen in FIG. 4, the offset voltage sources on each RX channel are different (e.g., Voff1≠Voff2≠Voff3≠Voff4), and thus the measured waveform seen at each RX channel 201 will have a different DC component, although the drive signal of each RX channel 201 is the same. Thus, the DC offset at each RX channel will be individualized. The leakage resistance (or shorts) between individual sensors cause DC currents between sensors connected to different offset voltage sensing channels and/or cause DC currents between a sensor 205 connected to an offset voltage channel and a sensor 205 connected to the shield generator 203. This DC current causes a half period data imbalance (illustrated in FIG. 6) and shorts can be detected by calculating the half period imbalance value. The touch response has no impact on the data imbalance (in the ideal case). It should be noted that the DC offset values for each RX channel 201 should be small enough to prevent any impact on a displayed image.

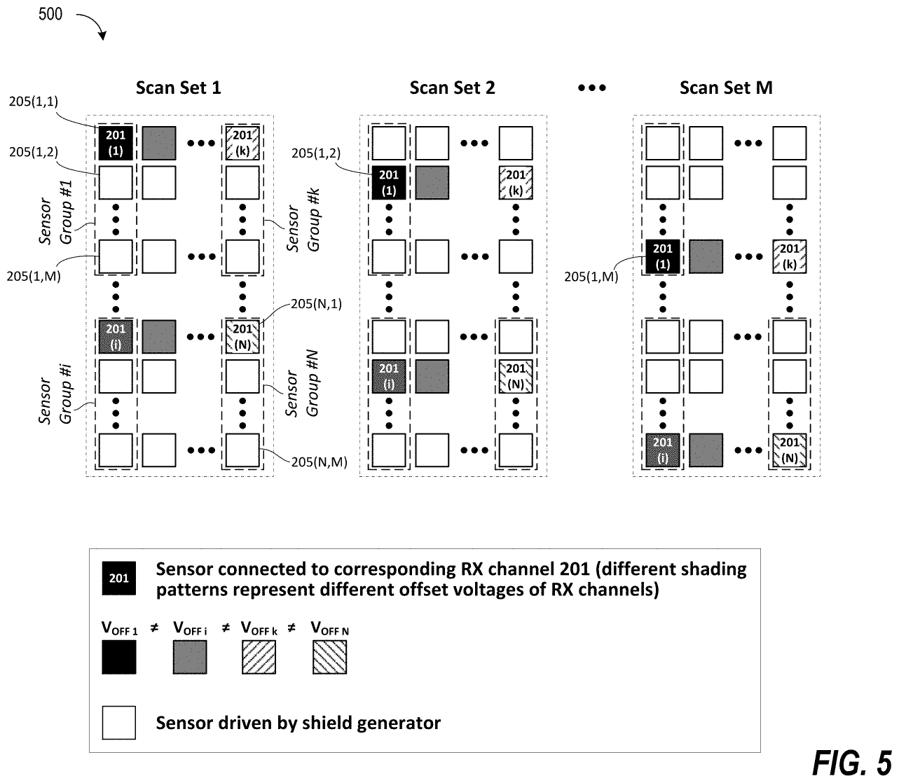

FIG. 5 illustrates a shorts test sequence using individual offset voltages for each RX channel 201. The touch screen controller 200 may initiate a touch scan of the sensors 205 (e.g., to detect the capacitance values therefrom). More specifically, the touch screen controller 200 may initiate a first scan set wherein a first sensor of (the sensor group corresponding to) each available RX channel 201 is scanned in parallel (the sensors being scanned in each scan are shaded; different shading colors and patterns represent different offset voltages of RX channels), while the remaining sensors are shielded. During this first scan set, each RX channel 201 may produce samples during excitation. Each RX channel 201 produces one sample for each half period of excitation (as shown in FIG. 6). As can be seen in FIG. 6, half periods may be alternately odd and even. Referring back to FIG. 5, subsequently, touch screen controller 200 may perform a second scan set wherein a second sensor of each available RX channel 201 is scanned in parallel, while the remaining sensors are shielded. Again, each RX channel 201 may produce one sample for each half period of excitation. In this way, touch screen controller 200 may iteratively perform M scan sets, where M is the number of sensors in a sensor group.

When the touch information is accumulated for a sensor 205 during the scan, the magnitudes of even and odd samples (half periods) are summed and added. The touch response counts for a scan of a particular sensor on an RX channel 201 are thus calculated as:

T_{DATA}=ΣN_{EVEN}+ΣN_{ODD}

Detecting a short is based on the DC leakage current, given as the difference between even and odd sample magnitudes. Therefore, the DC leakage current for a scan of a particular sensor on an RX channel 201 is calculated as:

DC_{DATA}=ΣN_{EVEN}−ΣN_{ODD}

FIG. 6 illustrates graphs 600 of the half period data for RX channels 201(1) and 201(2) (having different voltage offsets) for 3 different situations (no short, channel-to-channel sensor short, and channel-to-shield sensor short). In FIG. 5, the shaded sensors may indicate sensors that are unshielded (e.g., connected to their respective RX channel 201 and being excited by the drive signal) during the scan, while unshaded sensors are those that are shielded during the scan. In an ideal situation (e.g., no shorts), half period data counts may be symmetrical for both RX channels 201(1) and 201(2), as shown by the “no shorts” graph. As used herein, half period data of an RX channel 201 may be symmetrical if the odd and even samples are similar in magnitude within some pre-defined level of deviation. As can be seen in the “no shorts” graph, the samples for the odd and even half periods (the half period data) are symmetrical for both RX channels 201(1) and 201(2).

By contrast, the “channel-to-channel” graph shows that the half period data for both RX channels 201(1) and 201(2) is asymmetrical, thus indicating a channel-to-channel sensor short (indicated by the leakage resistance (R_{L}) shown in FIG. 6). This asymmetry may be caused by the difference in the DC components of the drive signal for each of RX channels 201(1) and 201(2). As discussed above, the touch screen controller 120 may compare the difference between the half period data of any appropriate number of successive samples for RX channel 201(1) with a pre-defined deviation threshold and if the difference is beyond the threshold, may determine that a channel-to-channel sensor short has been detected (if RX channel 201(2) also has asymmetrical half period data).

The “channel-to-shield” graph indicates half period data of RX channels 201(1) and 201(2) when there is a short (indicated by the leakage resistance (R_{L}) shown in FIG. 6) between an unshielded sensor (connected to RX channel 201(1)) and a shielded sensor. All shielded sensors are driven by the same waveform which has the same AC component and different DC component (created by offset voltage sources) comparing to the waveforms of the sensors driven by RX channels. This may cause the asymmetry of the half period data as shown in the “channel-to-shield” graph. As can be seen in the “channel-to-shield” graph, the half period data for RX channel 201(1) is asymmetrical, while the half period data for RX channel 201(2) is symmetrical. This indicates a short between an unshielded sensor driven by RX channel 201(1) and a shielded sensor (e.g., a sensor that is being scanned and one that is not being scanned). Symmetrical half period data produced by the RX channel 201(2) indicates that the sensor driven by RX channel 201(2) is not shorted neither to shielded sensor nor to unshielded sensor.

In some embodiments, the use of individual DC offset voltages for short testing and diagnosis can be combined with correlated double sampling. The touch screen controller 200 may function to switch the DC offsets for each RX channel 201 ON and OFF. In this way, the touch screen controller 200 may calculate each sensor data half period imbalance twice, once when the DC offset is turned ON and once when the DC offset is turned OFF. For example, referring to FIG. 4, the touch screen controller 200 may initially scan a first sensor of each available RX channel 201 in parallel, while the remaining sensors are shielded. During this first scan however, the touch screen controller 200 may perform a first scan of a first sensor 205(1,1) wherein the DC offset (Voff1) is bypassed and calculate the half period data imbalance for the RX channel 201(1). The touch screen controller 200 may then perform a second scan of the first sensor 205(1,1) wherein the Voff1 is active, and calculate the half period data imbalance for the RX channel 201(1) again. The touch screen controller 200 may then determine the difference between the imbalance values when the Voff1 is active and when the Voff1 is bypassed. The touch screen controller 200 performs this scan method for a first sensor of each available RX channel 201 in parallel. If the magnitude of the difference in imbalance values for any of the sensors is greater than a predefined threshold, then the touch screen controller 200 may determine that those sensors are experiencing a short. The touch screen controller 200 then performs this scan method for a second sensor of each available RX channel 201 in parallel, until M scans have been performed (i.e., each sensor has been scanned in this way). The imbalance change may correspond to the leakage detection.

This concept allows canceling any RX channel internal data imbalance, e.g. due to the positive/negative IDAC currents mismatches, attenuator imperfections, etc. More specifically, during actual operation, the even/odd samples of half period data for an RX sensing channel are not ideally symmetrical, even if there are no shorted sensors. Due to manufacturing variances (such as poor matching of pos/neg baseline compensation iDAC sources, poor matching of attenuator gain for pos/neg current directions, and/or poor matching of pos/neg charge balancing iDAC sources, etc.), RX channel gain and/or offset may differ for positive and negative polarities of input sensing current. This causes inherent samples asymmetry (internal data imbalance). Although calibration procedures exist that allow for minimizing internal imbalance, some limited value still remains. This residual imbalance value may be treated by the diagnostics FW (touch screen controller 200) as a false short. However, use of the correlated double sampling technique (doing two readings with Voff1 OFF and ON and taking difference) cancels internal data imbalance value from the measurements. Therefore, only the imbalance data produced by the short remains in difference counts:

(1) Voff1 is OFF. Here ADC samples contain information about internal imbalance.
(2) Voff1 is ON. Here ADC samples contain data of internal imbalance+imbalance caused by a short.

If we take difference (2)−(1), only imbalance data caused by a short remains.

As can be seen, the use of individual DC offset voltages for short testing and diagnosis allows the short testing to be performed simultaneously with a touch scan (e.g., as part of the touch scan), and does not require a separate diagnostics scan. However, additional hardware in the form of programmable DC offset sources for each RX channel 201 is required to implement individualized DC offset voltages for each RX channel 201.

The touch screen controller 200 of FIG. 2 may also be used to detect opens among the sensors 205. When testing for opens, the touch screen controller may utilize AC current sensing. The presence of an open may change the baseline capacitance seen by the sensing RX channel 201 and thus change the ADC conversion result. Open testing and detection may be performed during manufacture and during operation. For on-cell panels, the combination of self-capacitance and mutual-capacitance (Cp/Cm) scans is used to detect opens. ADC readings in self-capacitance sensing mode for electrodes with broken connection may differ significantly from typical manufacturing variation limits, and/or ADC readings in mutual-capacitance sensing mode for intersections formed by broken electrodes may differ significantly from typical manufacturing variation limits. For in-cell panels, open detection may be performed during an LCD optical manufacturing-time test. During such a manufacturing test, floating VCOM sensors with a broken connection to the touch screen controller 200 may cause distortion of a test image pattern.

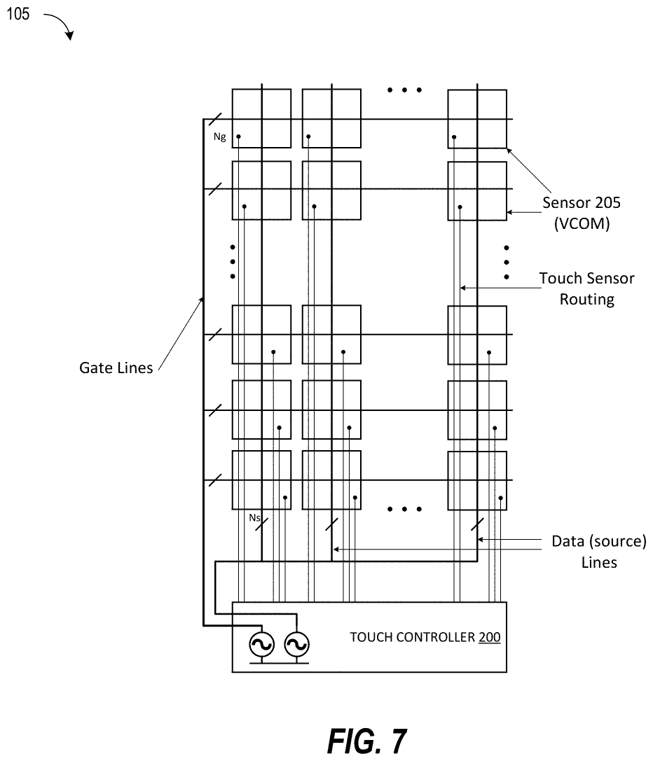

During operation of in-cell panels, opens testing and detection may be done with capacitive sensing. However, during a scan of the sensors 111 (e.g., a capacitive sensing time window), the shield generator 203 may apply a compensation signal (e.g., a copy of the waveform of the sensors 205 driven by RX channels 201) to gate lines and data lines of the display (See FIG. 7). This run-time active shielding technique removes baseline capacitance from ADC readings, which in turn hides possible opens that are within an acceptable panel non-uniformity range. As a result, the baseline capacitance must be restored to make the system sensitive to opens. FIG. 7 illustrates the touch screen panel 105 (as a true in-cell panel) with gate and data (source) TFT lines driven by the touch screen controller 200. Baseline restoral (full or partial) can be accomplished during run-time of the touch screen panel 105 in the following ways:
Touch screen controller 200 may change the amplitude of the compensation signal applied to gate and/or data TFT lines (FIG. 7). The goal is to make the amplitude of the compensation signal waveform different from the amplitude of the waveform produced by RX channels 201.
Touch screen controller 200 may change the phase of the compensation signal applied to the gate and/or data TFT lines to make the phase of the compensation signal waveform different from the phase of the waveform produced by RX channels 201.
Touch screen controller 200 may change both the amplitude and the phase of the shield signal applied to the gate and/or data TFT lines.
Touch screen controller 200 may maintain the sensor and gate lines with same normal compensation signal and change/modulate the compensation signal only the data TFT lines. Gate lines open the TFT structure and may change the charge on a storage capacitor of an individual TFT pixel. During restoration of the baseline capacitance, it is important to not introduce any distortion to the displayed image. Thus, not changing the compensation signal of the gate and sensor lines, the integrity of the displayed image may be maintained.

After the baseline capacitance (Cp) is restored, the touch screen controller 200 can verify if the ADC readings are within normal operation range limits. The touch screen controller 200 reports a test failure if the measured data exceeds the operation range limits. The touch screen controller 200 may use reference data from a panel that is known to be free of opens/shorts to establish limits on the operation range for purposes of comparison.

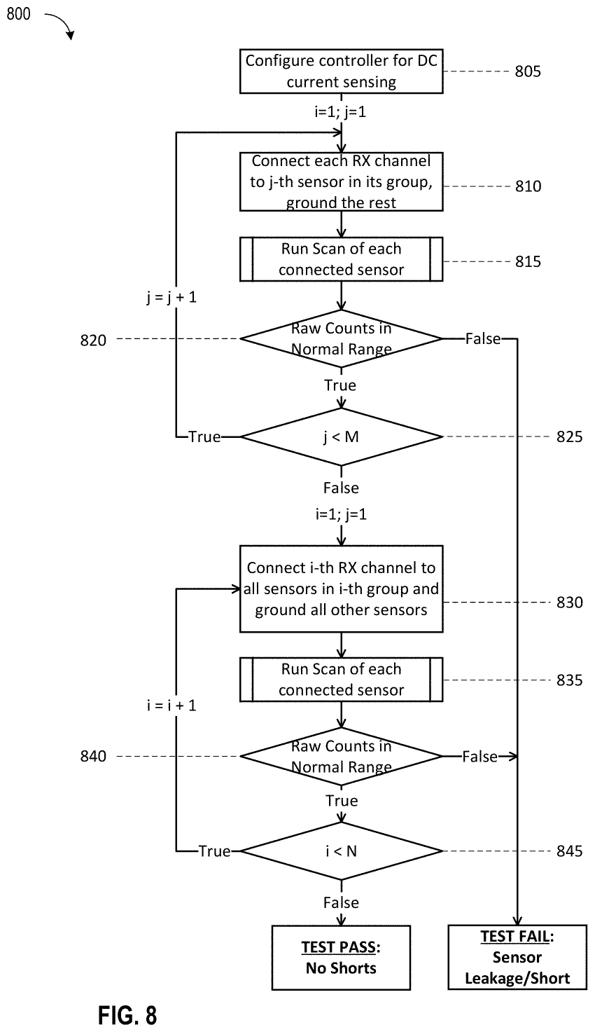

FIG. 8 is a flow diagram of a method 800 of detecting shorts, in accordance with some embodiments of the present disclosure. Method 800 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. For example, the method 800 may be performed by the touch screen controller 200 executing short detection firmware.

Referring also to FIGS. 2, 3A, and 3B, at block 805, The touch screen controller may be configured for DC current sensing. The touch screen controller 200 may perform M scan sets, each of the M scan sets using (scanning) all of the RX channels 201 in parallel. During each of the M scan sets, only one sensor 205 in each sensor group is connected (indicated in FIG. 3A by shaded sensors 205) to the corresponding RX channel 201 at the moment of scan. At block 810, the touch screen controller 200 may connect the j^{th} sensor 205(i,j) (indicated in FIG. 3A by shaded sensors 205) in each i^{th} group to its corresponding l^{th} RX channel 201(i) and at block 815, may perform a scan of each of the connected sensors 205. Touch screen controller 200 may perform a DC scan, so no AC excitation may be applied to the connected sensors 205. Unused sensors 205 (indicated in FIG. 3A by unshaded sensors 205) are connected to GND via their respective multiplexer 204. At block 820, the touch screen controller 200 may determine if the measurements from the scan are within a manufacturing variation range. More specifically, there is some potential of the connected sensor 205 that differs from GND (or a programmable DC level) of the unused sensors 205 and this difference in voltage forms a current pass which forms a leakage current which may be detected and compared to the manufacturing variation range. Touch screen controller 200 may perform the remaining M scan sets (until shown at block 825) in a similar manner, sequentially connecting each RX channel 201 to a different sensor 205 of its group each time until each sensor 205 has been scanned. The touch screen controller 200 may perform each of the M scan sets in this way, and then check the ADC readings to determine if they are within a manufacturing variation range. The touch screen controller 200 may report a test failure if the measured data for any sensor 205 exceeds the manufacturing variation range limits.

Touch screen controller 200 may then commence the second stage of the DC current sensing method wherein the touch screen controller 200 may detect shorts between sensor groups. The touch screen controller 200 may perform N scan sets sequentially, where for each scan set, a single channel 201 is connected to all sensors 205 (indicated in FIG. 3B by shaded sensors 205) in the corresponding sensor group. At block 830, a i^{th} RX channel 201(i) may be connected to all of the sensors 205(i,1)-205(i,M) (indicated in FIG. 3B by shaded sensors 205) in its corresponding l^{th} sensor group, and unused sensors (e.g., sensors 205 on any other RX channel 201, indicated in FIG. 3B by unshaded sensors 205) are connected to GND (or a programmable DC source). For example, in a first scan set, RX channel 201(1) may be connected to sensors 205(1,1)-205(1,M) (e.g., the sensors in sensor group 1). At block 835, the touch screen controller 200 may then perform a scan of each of the connected sensors and at block 840 may check the ADC readings to determine if they are within a manufacturing variation range. The FW reports a test failure if measurement data exceeds the manufacturing variation range limits (i.e. the query at block 840 is false). At block 845, the touch screen controller 200 may perform each of the N scan sets in this way (until i≥N), until each sensor 205 has been scanned. If the measurement data for all sensors is within the manufacturing variation range limits (i.e. the query at block 840 is true for each of the N scans), then touch screen controller 200 may report that the test has passed.

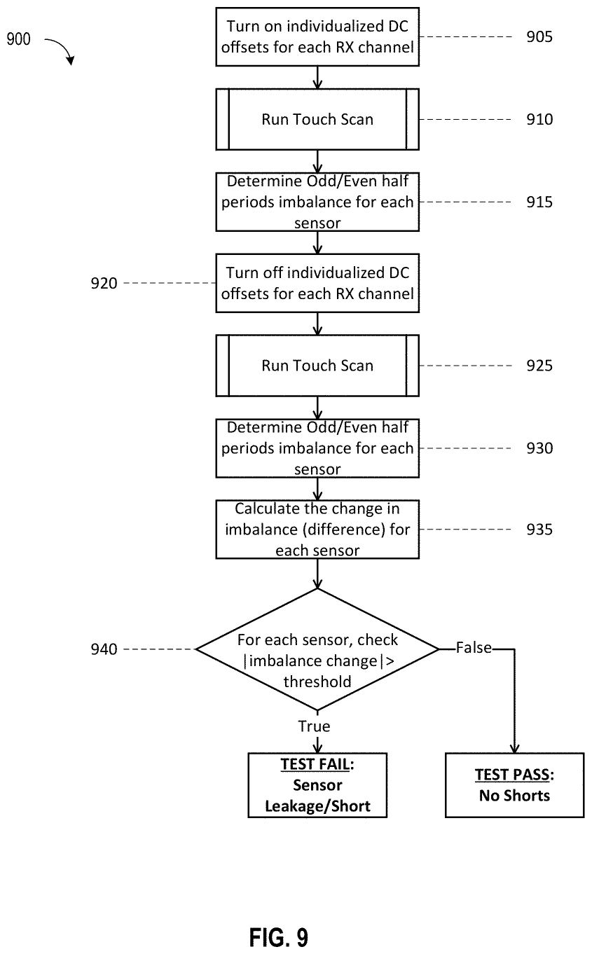

FIG. 9 is a flow diagram of a method 900 of detecting shorts, in accordance with some embodiments of the present disclosure. Method 900 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. For example, the method 900 may be performed by the touch screen controller 200 executing short detection firmware.

Referring also to FIGS. 4, 5, and 6, at block 905 the touch screen controller 200 may initiate offset voltage sources on each RX channel, and each offset voltage source may be different (e.g., Voff1 Voff2 Voff3 Voff4). Thus, the measured waveform seen at each RX channel 201 will have a different DC component, although the drive signal (AC component) of each RX channel 201 is the same. The leakage resistance (or shorts) between individual sensors cause DC currents between sensors connected to different offset voltage sensing channels and/or cause DC currents between a sensor 205 connected to an offset voltage channel and a sensor 205 connected to the shield generator 203. This DC current causes a half period data imbalance (illustrated in FIG. 6) and shorts can be detected by calculating the half period imbalance value. The touch response has no impact on the data imbalance (in the ideal case). It should be noted that the DC offset values for each RX channel 201 should be small enough to prevent any impact on a displayed image.

At block 910, the touch screen controller 200 may initiate a touch scan of the sensors 205 (e.g., to detect the capacitance values therefrom). More specifically, the touch screen controller 200 may initiate a first scan set wherein a first sensor of (the sensor group corresponding to) each available RX channel 201 is scanned in parallel (the sensors being scanned in each scan indicated as shaded sensors in FIG. 5), while the remaining sensors are shielded (indicated by unshaded sensors in FIG. 5). During this first scan set, each RX channel 201 may produce samples during excitation. Each RX channel 201 produces one sample for each half period of excitation (as shown in FIG. 6). As can be seen in FIG. 6, half periods may be alternately odd and even. Referring back to FIG. 5, subsequently, touch screen controller 200 may perform a second scan set wherein a second sensor of each available RX channel 201 is scanned in parallel, while the remaining sensors are shielded. Again, each RX channel 201 may produce one sample for each half period of excitation. In this way, touch screen controller 200 may iteratively perform M scan sets, where M is the number of sensors in a sensor group. At block 915, the touch screen controller 200 may determine the half period imbalance for each sensor 205.

At block 920, the touch screen controller 200 may deactivate the offset voltage sources on each channel and at block 925 may run another touch scan. At block 930, the touch screen controller 200 may determine the half period imbalance for each sensor 205 and calculate the change in imbalance (difference between half period imbalance with and without offset voltages) for each sensor 205. At block 940, the touch screen controller 200 may determine whether the difference in half period imbalance for each sensor 205 is greater than or less than a threshold difference. If the difference in half period imbalance for all sensors 205 is less than the threshold, then touch screen controller 200 may report that the test is successful and that no shorts were detected. If the difference in half period imbalance for any sensors 205 is greater than the threshold, then touch screen controller 200 may determine that a short has been detected and report the test as failed.

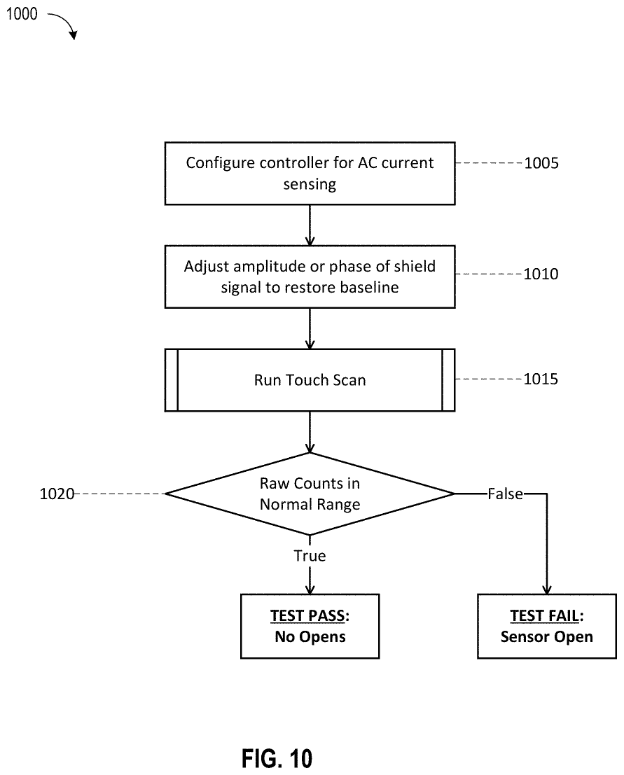

FIG. 10 is a flow diagram of a method 1000 of detecting opens, in accordance with some embodiments of the present disclosure. Method 1000 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. For example, the method 1000 may be performed by the touch screen controller 200 executing open detection firmware.

Referring also to FIG. 7, at block 1005, the touch screen controller may configure itself for AC current sensing. The presence of an open may change the baseline capacitance seen by an RX channel 201 and thus change the ADC conversion result. Open testing and detection may be performed during manufacture and during operation. For on-cell panels, the combination of self-capacitance and mutual-capacitance (Cp/Cm) scans is used to detect opens. ADC readings in self-capacitance sensing mode for electrodes with broken connection may differ significantly from typical manufacturing variation limits, and/or ADC readings in mutual-capacitance sensing mode for intersections formed by broken electrodes may differ significantly from typical manufacturing variation limits. For in-cell panels, open detection may be performed during an LCD optical manufacturing-time test. During such a manufacturing test, floating VCOM sensors with a broken connection to the touch screen controller 200 may cause distortion of a test image pattern.

During operation of in-cell panels, opens testing and detection may be done with capacitive sensing. However, during a scan of the sensors 111 (e.g., a capacitive sensing time window), the shield generator 203 may apply a compensation signal (e.g., a copy of the waveform of the sensors 205 driven by RX channels 201) to gate lines and data lines of the display (See FIG. 7). This run-time active shielding technique removes baseline capacitance from ADC readings, which in turn hides possible opens that are within an acceptable panel non-uniformity range. As a result, at block 1010, the touch screen controller 200 may restore the baseline capacitance to make the system sensitive to opens. FIG. 7 illustrates the touch screen panel 105 (as a true in-cell panel) with gate and data (source) TFT lines driven by the touch screen controller 200. Baseline restoral (full or partial) can be accomplished during run-time of the touch screen panel 105 in the following ways:
Touch screen controller 200 may change the amplitude of the compensation signal applied to gate and/or data TFT lines (FIG. 7). The goal is to make the amplitude of the compensation signal waveform different from the amplitude of the waveform produced by RX channels 201.
Touch screen controller 200 may change the phase of the compensation signal applied to the gate and/or data TFT lines to make the phase of the compensation signal waveform different from the phase of the waveform produced by RX channels 201.
Touch screen controller 200 may change both the amplitude and the phase of the shield signal applied to the gate and/or data TFT lines.
Touch screen controller 200 may maintain the sensor and gate lines with same normal compensation signal and change/modulate the compensation signal only the data TFT lines. Gate lines open the TFT structure and may change the charge on a storage capacitor of an individual TFT pixel. During restoration of the baseline capacitance, it is important to not introduce any distortion to the displayed image. Thus, not changing the compensation signal of the gate and sensor lines, the integrity of the displayed image may be maintained.

After the baseline capacitance (Cp) is restored, the touch screen controller 200 may perform a touch scan at block 1015 and may verify if the ADC readings (raw counts) are within normal operation range limits at block 1020. The touch screen controller 200 reports a test failure if the measured data exceeds the operation range limits. The touch screen controller 200 may use reference data from a panel that is known to be free of opens/shorts to establish limits on the operation range for purposes of comparison.

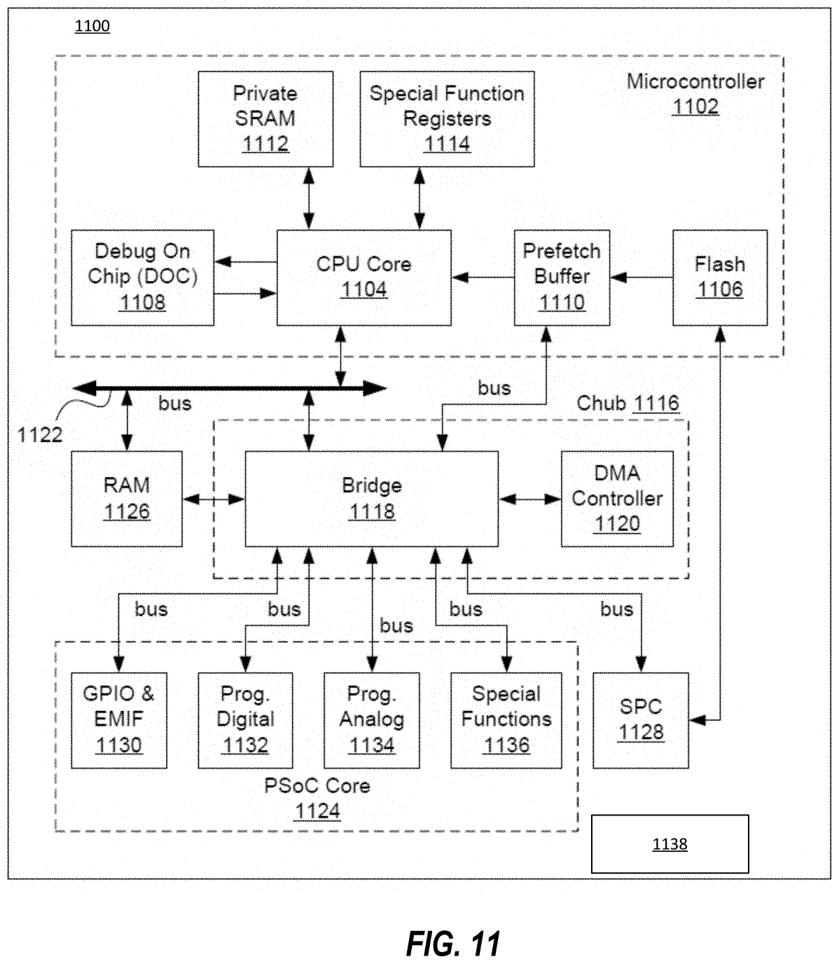

FIG. 11 illustrates an embodiment of a core architecture 1100 of the PSoC® controller or a processing element capable of performing the sensor short and open detection as previously disclosed, such as that used in the PSoC3® family of products offered by Cypress Semiconductor Corporation (San Jose, Calif.). In one embodiment, the core architecture 1100 includes a microcontroller 1102. The microcontroller 1102 includes a CPU (central processing unit) core 1104 (which may correspond to processing device 130 of FIG. 1 or processing device 206 of FIG. 2), flash program storage 1106, DOC (debug on chip) 1108, a prefetch buffer 1110, a private SRAM (static random access memory) 1112, and special functions registers 1114. In an embodiment, the DOC 1108, prefetch buffer 1110, private SRAM 1112, and special function registers 1114 are coupled to the CPU core 1104 (e.g., CPU core 1006), while the flash program storage 1106 is coupled to the prefetch buffer 1110.

The core architecture 1100 may also include a CHub (core hub) 1116, including a bridge 1118 and a DMA controller 1120 that is coupled to the microcontroller 1102 via bus 1122. The CHub 1116 may provide the primary data and control interface between the microcontroller 1102 and its peripherals (e.g., peripherals) and memory, and a programmable core 1124. The DMA controller 1120 may be programmed to transfer data between system elements without burdening the CPU core 1104. In various embodiments, each of these subcomponents of the microcontroller 1102 and CHub 1116 may be different with each choice or type of CPU core 1104. The CHub 1116 may also be coupled to shared SRAM 1126 and an SPC (system performance controller) 1128. The private SRAM 1112 is independent of the shared SRAM 1126 that is accessed by the microcontroller 1102 through the bridge 1118. The CPU core 1104 accesses the private SRAM 1112 without going through the bridge 1118, thus allowing local register and RAM accesses to occur simultaneously with DMA access to shared SRAM 1126. Although labeled here as SRAM, these memory modules may be any suitable type of a wide variety of (volatile or non-volatile) memory or data storage modules in various other embodiments.

In various embodiments, the programmable core 1124 may include various combinations of subcomponents (not shown), including, but not limited to, a digital logic array, digital peripherals, analog processing channels, global routing analog peripherals, DMA controller(s), SRAM and other appropriate types of data storage, IO ports, and other suitable types of subcomponents. In one embodiment, the programmable core 1124 includes a GPIO (general purpose IO) and EMIF (extended memory interface) block 1130 to provide a mechanism to extend the external off-chip access of the microcontroller 1102, a programmable digital block 1132, a programmable analog block 1134, and a special functions block 1136, each configured to implement one or more of the subcomponent functions. In various embodiments, the special functions block 1136 may include dedicated (non-programmable) functional blocks and/or include one or more interfaces to dedicated functional blocks, such as USB, a crystal oscillator drive, JTAG, and the like.

The programmable digital block 1132 may include a digital logic array including an array of digital logic blocks and associated routing. In one embodiment, the digital block architecture is comprised of UDBs (universal digital blocks). For example, each UDB may include an ALU together with CPLD functionality.

In various embodiments, one or more UDBs of the programmable digital block 1132 may be configured to perform various digital functions, including, but not limited to, one or more of the following functions: a basic I2C slave; an I2C master; a SPI master or slave; a multi-wire (e.g., 3-wire) SPI master or slave (e.g., MISO/MOSI multiplexed on a single pin); timers and counters (e.g., a pair of 8-bit timers or counters, one 16 bit timer or counter, one 8-bit capture timer, or the like); PWMs (e.g., a pair of 8-bit PWMs, one 16-bit PWM, one 8-bit deadband PWM, or the like), a level sensitive I/O interrupt generator; a quadrature encoder, a UART (e.g., half-duplex); delay lines; and any other suitable type of digital function or combination of digital functions which can be implemented in a plurality of UDBs.

In other embodiments, additional functions may be implemented using a group of two or more UDBs. Merely for purposes of illustration and not limitation, the following functions can be implemented using multiple UDBs: an I2C slave that supports hardware address detection and the ability to handle a complete transaction without CPU core (e.g., CPU core 1104) intervention and to help prevent the force clock stretching on any bit in the data stream; an I2C multi-master which may include a slave option in a single block; an arbitrary length PRS or CRC (up to 32 bits); SDIO; SGPIO; a digital correlator (e.g., having up to 32 bits with 4× over-sampling and supporting a configurable threshold); a LINbus interface; a delta-sigma modulator (e.g., for class D audio DAC having a differential output pair); an I2S (stereo); an LCD drive control (e.g., UDBs may be used to implement timing control of the LCD drive blocks and provide display RAM addressing); full-duplex UART (e.g., 7-, 8- or 9-bit with 1 or 2 stop bits and parity, and RTS/CTS support), an IRDA (transmit or receive); capture timer (e.g., 16-bit or the like); deadband PWM (e.g., 16-bit or the like); an SMbus (including formatting of SMbus packets with CRC in software); a brushless motor drive (e.g., to support 6/12 step commutation); auto BAUD rate detection and generation (e.g., automatically determine BAUD rate for standard rates from 1200 to 115200 BAUD and after detection to generate required clock to generate BAUD rate); and any other suitable type of digital function or combination of digital functions which can be implemented in a plurality of UDBs.

The programmable analog block 1134 may include analog resources including, but not limited to, comparators, mixers, PGAs (programmable gain amplifiers), TIAs (trans-impedance amplifiers), ADCs (analog-to-digital converters), DACs (digital-to-analog converters), voltage references, current sources, sample and hold circuits, and any other suitable type of analog resources. The programmable analog block 1134 may support various analog functions including, but not limited to, analog routing, LCD drive TO support, capacitance-sensing, voltage measurement, motor control, current to voltage conversion, voltage to frequency conversion, differential amplification, light measurement, inductive position monitoring, filtering, voice coil driving, magnetic card reading, acoustic doppler measurement, echo-ranging, modem transmission and receive encoding, or any other suitable type of analog function.

The embodiments described herein may be used in various designs of mutual-capacitance sensing systems, in self-capacitance sensing systems, or combinations of both. The embodiments described herein are not tied to a particular capacitive sensing solution and can be used as well with other sensing solutions, including optical sensing solutions, as would be appreciated by one of ordinary skill in the art having the benefit of this disclosure.

In the above description, numerous details are set forth. It will be apparent, however, to one of ordinary skill in the art having the benefit of this disclosure, that embodiments of the present disclosure may be practiced without these specific details. In some instances, well-known structures and devices are shown in block diagram form, rather than in detail, in order to avoid obscuring the description.

Some portions of the detailed description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “determining,” “detecting,” “comparing,” “resetting,” “adding,” “calculating,” or the like, refer to the actions and processes of a computing system, or similar electronic computing device, that manipulates and transforms data represented as physical (e.g., electronic) quantities within the computing system's registers and memories into other data similarly represented as physical quantities within the computing system memories or registers or other such information storage, transmission or display devices.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such.

Embodiments descried herein may also relate to an apparatus for performing the operations herein. This apparatus may be specially constructed for the required purposes, or it may comprise a general-purpose computer selectively activated or reconfigured by a computer program stored in the computer. Such a computer program may be stored in a non-transitory computer-readable storage medium, such as, but not limited to, any type of disk including floppy disks, optical disks, CD-ROMs and magnetic-optical disks, read-only memories (ROMs), random access memories (RAMs), EPROMs, EEPROMs, magnetic or optical cards, flash memory, or any type of media suitable for storing electronic instructions. The term “computer-readable storage medium” should be taken to include a single medium or multiple media (e.g., a centralized or distributed database and/or associated caches and servers) that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The algorithms and displays presented herein are not inherently related to any particular computer or other apparatus. Various general-purpose systems may be used with programs in accordance with the teachings herein, or it may prove convenient to construct a more specialized apparatus to perform the required method steps. The required structure for a variety of these systems will appear from the description below. In addition, the present embodiments are not described with reference to any particular programming language. It will be appreciated that a variety of programming languages may be used to implement the teachings of the embodiments as described herein.

The above description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present embodiments. Thus, the specific details set forth above are merely exemplary. Particular implementations may vary from these exemplary details and still be contemplated to be within the scope of the present embodiments.

It is to be understood that the above description is intended to be illustrative and not restrictive. Many other embodiments will be apparent to those of skill in the art upon reading and understanding the above description. The scope of the embodiments should, therefore, be determined with reference to the appended claims, along with the full scope of equivalents to which such claims are entitled.

What is claimed is:

1. An apparatus comprising:
one or more receive channels, each receive channel configured to scan a corresponding group of sensors of a plurality of sensors;
a plurality of multiplexers, each multiplexer configured to selectively couple a respective sensor of the plurality of sensors to a corresponding receive channel or a reference voltage; and
a processing device configured to:
detect one or more shorts among the plurality of sensors based on DC current sensing; and
detect one or more opens among the plurality of sensors based on AC current sensing of each of the one or more receive channels.

2. The apparatus of claim 1, wherein to detect the one or more shorts, the processing device is configured to:
iteratively, until each of the plurality of sensors has been scanned, connect a single unscanned sensor of each group of sensors to a corresponding receive channel to scan the single sensor of each group of sensors in parallel, while each other sensor in the plurality of sensors is connected to a reference voltage; and
scan each group of sensors sequentially, wherein to scan a group of sensors the processing device is configured to:
connect each of the sensors in the group of sensors to a corresponding receive channel to scan each of the sensors in the group of sensors in parallel.

3. The apparatus of claim 2, wherein the reference voltage is a compensation signal applied to the plurality of sensors to minimize the capacitance seen by each receive channel.

4. The apparatus of claim 1, further comprising:
one or more offset voltage sources, each of the one or more offset voltage sources coupled to a respective receive channel, wherein the processing device is configured to detect the one or more shorts based on a DC leakage current from a scan of each of the plurality of sensors.

5. The apparatus of claim 4, wherein to detect the one or more shorts, the processing device is configured to:
iteratively, until each of the plurality of sensors has been scanned:
connect a single unscanned sensor of each group of sensors to a corresponding receive channel to scan the single sensor of each group of sensors in parallel, while each other sensor in the plurality of sensors are shielded; and
determine whether any shorts exist based on half period data generated by each receive channel while scanning the single sensor of each group of sensors in parallel.

6. The apparatus of claim 4, wherein detecting the one or more shorts based on a DC leakage current occurs as part of a touch scan.

7. The apparatus of claim 1, further comprising a shield generator configured to apply a compensation signal to the plurality of sensors to minimize a baseline capacitance of each receive channel and to detect the one or more opens, wherein the processing device is configured to:
restore the baseline capacitance of each receive channel;
scan, via the one or more receive channels, each of the plurality of sensors; and
detect one or more opens based on a comparison of analog to digital converter readings from each receive channel with normal operation range data.

8. A system comprising:
a touch panel comprising a plurality of sensors; and
a touch screen controller operatively coupled to the touch panel, the touch screen controller comprising: one or more receive channels, each receive channel configured to scan a corresponding group of sensors of the plurality of sensors, the touch screen controller configured to:
apply a compensation signal to one or more of gate lines and data lines of the touch panel to minimize a baseline capacitance of each receive channel;
detect one or more shorts among the plurality of sensors based on DC current sensing; and
detect one or more opens among the plurality of sensors based on AC current sensing of each of the one or more receive channels.

9. The system of claim 8, wherein to detect the one or more opens based on AC current sensing, the touch screen controller is configured to:
restore a baseline capacitance of each receive channel;
scan, via the one or more receive channels, each of the plurality of sensors; and
detect one or more opens based on a comparison of analog to digital converter readings from each receive channel with normal operation range data.

10. The system of claim 9, wherein to restore the baseline capacitance of each receive channel, the touch screen controller is configured to:
modify one or more of an amplitude and phase of the compensation signal to make a waveform of the compensation signal different from a waveform produced by each receive channel; or
maintain the compensation signal with respect to the gate lines, and modify one or more of an amplitude and phase of the compensation signal with respect to the data lines.

11. The system of claim 8, wherein the touch screen controller is operatively coupled to the touch panel in a true in-cell configuration.

12. The system of claim 8, wherein to detect the one or more shorts, the touch screen controller is configured to:
iteratively, until each of the plurality of sensors has been scanned, connect a single unscanned sensor of each group of sensors to a corresponding receive channel to scan the single sensor of each group of sensors in parallel, while each other sensor in the plurality of sensors is connected to a reference voltage; and
scan each group of sensors sequentially, wherein to scan a group of sensors the touch screen controller is to:
connect each of the sensors in the group of sensors to a corresponding receive channel to scan each of the sensors in the group of sensors in parallel.

13. The system of claim 12, wherein the reference voltage is the compensation signal.

14. The system of claim 8, wherein the touch screen controller further comprises one or more offset voltage sources, each of the one or more offset voltage sources coupled to a respective receive channel, and wherein to detect the one or more shorts, the touch screen controller is configured to:
iteratively, until each of the plurality of sensors has been scanned:
connect a first sensor of each group of sensors to a corresponding receive channel to scan the first sensor of each group of sensors in parallel, while each other sensor in the plurality of sensors are shielded; and
determine whether any shorts exist based on half period data generated by each receive channel while scanning the first sensor of each group of sensors in parallel.

15. A method comprising:
initiating one or more direct current (DC) offset voltage sources, each of the one or more offset voltage sources operatively coupled to a receive channel of one or more receive channels, and each of the one or more receive channels configured to scan a corresponding group of sensors of a plurality of sensors;
iteratively, until each of the plurality of sensors has been scanned, connecting a single unscanned sensor of each group of sensors to a corresponding receive channel to scan the single sensor of each group of sensors in parallel, while each other sensor in the plurality of sensors are shielded; and
determining whether any shorts exist among the plurality of sensors based on half period data generated by each receive channel while scanning the first sensor of each group of sensors in parallel.

16. The method of claim 15, wherein each of the plurality of sensors is coupled to a respective multiplexer of a plurality of multiplexers, and each multiplexer is configured to selectively couple a respective sensor of the plurality of sensors to a corresponding receive channel or a reference voltage.

17. The method of claim 15, wherein half period data generated by a receive channel while scanning a sensor comprises even samples having a first magnitude generated at even half periods and odd samples having a second magnitude generated at odd half periods.

18. The method of claim 17, wherein a short of the sensor is based on a DC leakage current of the sensor, and the DC leakage current of the sensor comprises a difference in magnitude between even samples and odd samples of half period data of the sensor.

19. The method of claim 16, wherein the reference voltage is a compensation signal applied to the plurality of sensors to minimize a baseline capacitance of each receive channel.

20. The method of claim 19, further comprising:
restoring the baseline capacitance of each receive channel;
scanning each of the plurality of sensors; and
detecting one or more opens based on a comparison of analog to digital converter readings from each receive channel with normal operation range data.
